(19) United States
(12) Patent Application Publication
(10) Pub. No.: US 2026/0186413 A1
(43) Pub. Date: Jul. 2, 2026

(54) PHOTOSENSITIVE RESIN COMPOSITION, PHOTOSENSITIVE ELEMENT, METHOD FOR FORMING RESIST PATTERN, AND METHOD FOR PRODUCING SEMICONDUCTOR PACKAGE OR PRINTED WIRING BOARD

(71) Applicant: Resonac Corporation, Tokyo (JP)

(72) Inventors: Tetsuya KATO, Tokyo (JP); Kenichi IWASHITA, Tokyo (JP); Ayaka KURODA, Tokyo (JP); Hiroshi ONO, Tokyo (JP); Yosuke KAGUCHI, Tokyo (JP); Natsuki TODA, Tokyo (JP)

(21) Appl. No.: 18/858,153

(22) PCT Filed: Jun. 28, 2023
(86) PCT No.: PCT/JP2023/024004

§ 371 Date: Oct. 18, 2024

(30) Foreign Application Priority Data
Jul. 6, 2022 (WO) PCT/JP2022/026834

(51) Int. Cl. G03F 7/029; G03F 7/033; G03F 7/16; H10W 70/05

(52) U.S. Cl. CPC G03F 7/0295; G03F 7/033; G03F 7/161; H10W 70/05

(57) ABSTRACT

This photosensitive resin composition contains (A) a binder polymer, (B) a photopolymerizable compound having an ethylenically unsaturated bond, and (C) a photopolymerization initiator, in which the photosensitive resin composition has an absorbance with respect to light at a wavelength of 365 nm per 1 μm of thickness of more than 0.0041 and 0.0130 or less.

### TECHNICAL FIELD

The present disclosure relates to a photosensitive resin composition, a photosensitive element, a method for forming a resist pattern, and a method for producing a semiconductor package substrate or printed wiring board.

### BACKGROUND ART

In the field of the production of semiconductor package substrates and printed wiring boards, a photosensitive resin composition, and a photosensitive element (laminate) having a structure in which a layer containing the photosensitive resin composition (hereinafter referred to as a “photosensitive layer”) is formed on a support and a protective film is arranged on the photosensitive layer have been widely used as a resist material used for etching, plating, or the like.

In a case of the production of a semiconductor package substrate or printed wiring board using a photosensitive element, first, a photosensitive layer of the photosensitive element is laminated on a substrate for forming a circuit. Next, a predetermined portion of the photosensitive layer is irradiated with active light rays to cure the exposed area. Thereafter, the support is removed by peeling, and the unexposed area of the photosensitive layer is then removed with a developer to form a resist pattern on the substrate. Next, the substrate on which the resist pattern has been formed is subjected to an etching treatment or a plating treatment using the resist pattern as a mask to form a circuit pattern on the substrate, and finally, the cured area (resist pattern) of the photosensitive layer is removed by peeling from the substrate.

As an exposure method, the photosensitive layer is subjected to patternwise exposure through a mask film or the like. In recent years, a projection exposure method in which the photosensitive layer is exposed by irradiation through a lens with active light rays projecting a photomask image has been used. As a light source used in the projection exposure method, an ultrahigh pressure mercury lamp is used. Generally, an exposure apparatus using i-line monochromatic light (365 nm) as an exposure wavelength is mostly used, but the exposure wavelengths of h-line monochromatic light (405 nm) and ihg mixed lines may be used in some cases.

The projection exposure system is an exposure system that can ensure a high resolution and a high alignment, as compared with a contact exposure system. Therefore, in recent years when there has been a demand for formation of finer circuits in semiconductor package substrates and printed wiring boards, the projection exposure system has attracted much attention.

With an increase in density of the semiconductor package substrates and the printed wiring boards in recent years, there has been an increasing demand for a photosensitive resin composition that is excellent in resolution and adhesiveness. Particularly, in the production of the package substrates, there is a demand for a photosensitive resin composition capable of forming a resist pattern with a line width/space width of 10/10 (unit: μm) or less. For example, in Patent Literature 1, it is investigated that the resolution and the adhesiveness are improved by using a specific photopolymerizable compound.

### CITATION LIST

### Patent Literature

Patent Literature 1: Japanese Unexamined Patent Publication No. 2013-195712

### SUMMARY OF INVENTION

### Technical Problem

As the density of semiconductor package substrates and printed wiring boards increases and the integration density of semiconductor packages also increases, there is a demand for a photosensitive resin composition that not only offers further improvement in resolution and adhesiveness but also is capable of forming a resist pattern having a good resist shape close to a rectangle.

Therefore, the present disclosure has an object to provide a photosensitive resin composition which is capable of forming a resist pattern having a good resist shape, and has good resolution and adhesiveness, a photosensitive element, a method for forming a resist pattern, and a method for producing a semiconductor package substrate or printed wiring board.

### Solution to Problem

The present disclosure provides a photosensitive resin composition, a photosensitive element, a method for forming a resist pattern, and a method for producing a semiconductor package substrate or printed wiring board, each shown below, in order to accomplish the object.
[1] A photosensitive resin composition containing (A) a binder polymer, (B) a photopolymerizable compound having an ethylenically unsaturated bond, and (C) a photopolymerization initiator, in which the photosensitive resin composition has an absorbance with respect to light at a wavelength of 365 nm per 1 μm of thickness of more than 0.0041 and 0.0130 or less.
[2] The photosensitive resin composition as described in [1], in which the photosensitive resin composition has an absorbance with respect to light at a wavelength of 365 nm per 1 μm of thickness of 0.0080 or less.
[3] The photosensitive resin composition as described in [1] or [2], in which a content of the (C) photopolymerization initiator is 3.0 parts by mass or more with respect to 100 parts by mass of a total amount of the (A) binder polymer and the (B) photopolymerizable compound.
[4] The photosensitive resin composition as described in any of [1] to [3], in which a content of the (C) photopolymerization initiator is 5.0 parts by mass or more with respect to 100 parts by mass of a total amount of the (A) binder polymer and the (B) photopolymerizable compound.
[5] The photosensitive resin composition as described in any of [1] to [4], further including (D) a sensitizer.
[6] The photosensitive resin composition as described in [5], in which the (D) sensitizer includes at least one selected from the group consisting of a dialkylaminobenzophenone compound, a pyrazoline compound, an anthracene compound, and a coumarin compound.
[7] The photosensitive resin composition as described in [5] or [6], in which a content of the (D) sensitizer is 0.03 parts by mass or less with respect to 100 parts by mass of the total amount of the (A) binder polymer and the (B) photopolymerizable compound.
[8] The photosensitive resin composition as described in any of [5] to [7], in which a mass ratio of a content of the (C) photopolymerization initiator to a content of the (D) sensitizer (the content of the (C) photopolymerization initiator/the content of the (D) sensitizer) is 80 or more.
[9] The photosensitive resin composition as described in any of [1] to [8], further including (E) a hydrogen donor, in which a content of the (E) hydrogen donor is 0.3 parts by mass or more with respect to 100 parts by mass of a total amount of the (A) binder polymer and the (B) photopolymerizable compound.
[10] The photosensitive resin composition as described in [9], in which the content of the (E) hydrogen donor is 0.55 parts by mass or more with respect to 100 parts by mass of the total amount of the (A) binder polymer and the (B) photopolymerizable compound.
[11] The photosensitive resin composition as described in [9] or [10], in which a total content of the (C) photopolymerization initiator and the (E) hydrogen donor is 4.0 parts by mass or more with respect to 100 parts by mass of the total amount of the (A) binder polymer and the (B) photopolymerizable compound.
[12] The photosensitive resin composition as described in any of [1] to [11], in which the photosensitive resin composition is used for formation of a resist pattern using a projection exposure system.
[13] A photosensitive element including a support and a photosensitive layer including the photosensitive resin composition as described in any of [1] to [12] formed on the support.
[14] The photosensitive element as described in [13], in which the support has a haze of 0.01% to 1.0%.
[15] The photosensitive element as described in [13] or [14], in which the number of particles having a diameter of 5 μm or more included in the support is 5 particles/mm² or less.
[16] The photosensitive element as described in any of [13] to [15], in which an intermediate containing a polyvinyl alcohol is included between the support and the photosensitive layer.
[17] A method for forming a resist pattern, the method including a photosensitive layer forming step of laminating a photosensitive layer including the photosensitive resin composition as described in any of [1] to [12] on a substrate, an exposure step of irradiating a predetermined portion of the photosensitive layer with active light rays to form a photocured area, and a development step of removing an area other than the predetermined portion of the photosensitive layer from the substrate.
[18] The method for forming a resist pattern as described in [17], in which in the exposure step, the active light rays are irradiated by a projection exposure system to form the photocured area.
[19] A method for forming a resist pattern, the method including a photosensitive layer forming step of laminating the photosensitive layer of the photosensitive element as described in any of [13] to [16] on a substrate, an exposure step of irradiating a predetermined portion of the photosensitive layer with active light rays to form a photocured area, and a development step of removing an area other than the predetermined portion of the photosensitive layer from the substrate.
[20] The method for forming a resist pattern as described in [19], in which in the exposure step, the active light rays are irradiated by a projection exposure system to form the photocured area.
[21] A method for producing a semiconductor package substrate or printed wiring board, the method including a step of subjecting a substrate on which a resist pattern is formed by the method for forming a resist pattern as described in [17] or [18] to an etching treatment or a plating treatment to form a conductor pattern.
[22] A method for producing a semiconductor package substrate or printed wiring board, the method including a step of subjecting a substrate on which a resist pattern is formed by the method for forming a resist pattern as described in [19] or [20] to an etching treatment or a plating treatment to form a conductor pattern.

### Advantageous Effects of Invention

According to the present disclosure, it is possible to provide a photosensitive resin composition which is capable of forming a resist pattern having a good resist shape, and has good resolution and adhesiveness, a photosensitive element, a method for forming a resist pattern, and a method for producing a semiconductor package substrate or printed wiring board.

### BRIEF DESCRIPTION OF DRAWINGS

FIG. 1 is a schematic cross-sectional view showing a photosensitive element according to one embodiment.

### DESCRIPTION OF EMBODIMENTS

Hereinafter, embodiments of the present disclosure will be described in detail. However, the present disclosure is not limited to the following embodiments.

In the present specification, a term “step” includes not only an independent step but also a step by which an intended action of the step is achieved even though the step cannot be clearly distinguished from other steps. In the present specification, a term “layer” is meant to include a structure having a shape formed over the entire surface as observed in a plan view, as well as a structure having a shape formed in a part. In the present specification, a term “(meth)acrylic acid” means at least one of “acrylic acid” and “methacrylic acid” corresponding thereto. The same applies to other analogous expressions such as (meth)acrylate.

In the present specification, a numerical value range that has been indicated by use of “to” indicates a range that includes the numerical values described before and after “to”, as the minimum value and the maximum value, respectively. In the numerical value ranges described stepwise in the present specification, the upper limit value or the lower limit value of a numerical value range at a certain stage may be substituted by the upper limit value or the lower limit value of a numerical value range at another stage. In addition, in a numerical value range described in the present specification, the upper limit value or the lower limit value of the numerical value range may be substituted by a value shown in Examples.

In the present specification, when reference is made to an amount of each component in a composition, in a case where a plurality of substances corresponding to each component exist in the composition, the amount of each component in the composition means a total amount of the plurality of substances that exist in the composition unless otherwise specified.

### [Photosensitive Resin Composition]

A photosensitive resin composition of the present embodiment contains a component (A): a binder polymer, a component (B): a photopolymerizable compound having an ethylenically unsaturated bond, and a component (C): a photopolymerization initiator. The photosensitive resin composition has an absorbance with respect to light at a wavelength of 365 nm per 1 μm of thickness of more than 0.0041 and 0.0130 or less.

By allowing the photosensitive resin composition of the present embodiment to contain the components (A) to (C) as essential components and to have an absorbance with respect to light at a wavelength of 365 nm per 1 μm of thickness of more than 0.0041 and 0.0130 or less, it is possible to form a resist pattern having a good resist shape as well as to obtain good resolution and adhesiveness.

The photosensitive resin composition of the present embodiment may contain a component (D): a sensitizer. Furthermore, the photosensitive resin composition of the present embodiment may contain a component (E): a hydrogen donor. In addition, the photosensitive resin composition of the present embodiment may further contain other components than the components (A) to (E). Hereinafter, each of components used in the photosensitive resin composition of the present embodiment will be described in more details.

### (Component (A): Binder Polymer)

The photosensitive resin composition includes one kind or two or more kinds of the components (A). Examples of the component (A) include acryl-based resins, styrene-based resins, epoxy-based resins, amide-based resins, amide epoxy-based resins, alkyd-based resins, and phenol-based resins. The component (A) may further include an acryl-based resin from the viewpoint of improving the alkali developability.

The acryl-based resin has, for example, a structural unit derived from (meth)acrylic acid, and may further have a structural unit derived from other monomers than (meth)acrylic acid. The other monomers may be of one kind or of two or more kinds.

The other monomers may include, for example, a (meth)acrylic acid ester. Examples of the (meth)acrylic acid ester include an alkyl (meth)acrylate ester, a cycloalkyl (meth)acrylate ester, and an aryl (meth)acrylate ester.

The other monomers may include the alkyl (meth)acrylate ester from the viewpoint of improving the alkali developability and the peeling characteristics. The alkyl group of the alkyl (meth)acrylate ester may be, for example, a methyl group, an ethyl group, a propyl group, a butyl group, a pentyl group, a hexyl group, a heptyl group, an octyl group, a nonyl group, a decyl group, an undecyl group, a dodecyl group, or structural isomers thereof, and from the viewpoint of further improving the peeling characteristics, the alkyl group may be an alkyl group having 1 to 4 carbon atoms.

In a case where the other monomers include an alkyl (meth)acrylate ester, a content of the alkyl (meth)acrylate ester may be 1% by mass or more, 2% by mass or more, or 3% by mass or more from the viewpoint of excellent peeling characteristics, and may be 80% by mass or less, 60% by mass or less, or 50% by mass or less from the viewpoint of further improving the resolution and the adhesiveness, each with respect to a total amount of the monomers constituting the component (A).

The other monomers may include styrene or a styrene derivative from the viewpoint of further improving the resolution and the adhesiveness. The styrene derivative may be, for example, vinyl toluene or α-methyl styrene.

In a case where the other monomers include styrene or a styrene derivative, a content of the styrene and the styrene derivative may be 40% by mass or more, 45% by mass or more, 47% by mass or more, or 50% by mass or more from the viewpoint of further improving the resolution, and may be 90% by mass or less, 85% by mass or less, or 80% by mass or less from the viewpoint of the developability, each with respect to the total amount of the monomers constituting the component (A).

The other monomers may include a hydroxyalkyl (meth)acrylate from the viewpoint of further improving the resolution and the adhesiveness. The hydroxyalkyl (meth)acrylate may be, for example, hydroxymethyl (meth)acrylate, hydroxyethyl (meth)acrylate, hydroxypropyl (meth)acrylate, hydroxybutyl (meth)acrylate, hydroxypentyl (meth)acrylate, or hydroxyhexyl (meth)acrylate. Furthermore, in a case where the alkyl moiety in the hydroxyalkyl (meth)acrylate unit has 3 or more carbon atoms, a branched structure may be included. By using an acryl-based resin having a structural unit derived from a hydroxyalkyl (meth)acrylate as the component (A), the minimum development time can be shortened, whereby the productivity can be improved and the lamination property of the photosensitive layer including the photosensitive resin composition can also be improved.

In a case where the other monomers include a hydroxyalkyl (meth)acrylate, the content of the hydroxyalkyl (meth)acrylate may be 0.5% by mass or more, 0.75% by mass or more, or 1.0% by mass or more from the viewpoint of the dispersibility, and may be 20% by mass or less, 15% by mass or less, or 8% by mass or less from the viewpoint of the water absorption, each with respect to the total amount of the monomers constituting the component (A).

In addition, examples of the other monomers include acrylamides such as diacetone acrylamide, acrylonitrile, ethers of vinyl alcohol such as vinyl-n-butyl ether, alkyl (meth)acrylate esters, benzyl (meth)acrylate esters such as benzyl methacrylate, tetrahydrofurfuryl (meth)acrylate esters, dimethylaminoethyl (meth)acrylate esters, diethylaminoethyl (meth)acrylate esters, glycidyl (meth)acrylate esters, 2,2,2-trifluoroethyl (meth)acrylate, 2,2,3,3-tetrafluoropropyl (meth)acrylate, α-bromoacrylic acid, α-chloroacrylic acid, β-furyl (meth)acrylic acid, β-styryl (meth)acrylic acid, maleic acid, maleic anhydride, maleic acid monoesters such as monomethyl maleate, monoethyl maleate, and monoisopropyl maleate, fumaric acid, cinnamic acid, α-cyanocinnamic acid, itaconic acid, crotonic acid, and propiolic acid.

An acid value of the component (A) may be 100 mgKOH/g or more, 120 mgKOH/g or more, 140 mgKOH/g or more, or 150 mgKOH/g or more from the viewpoint of suitable developability, and may be 250 mgKOH/g or less, 240 mgKOH/g or less, or 230 mgKOH/g or less from the viewpoint of improving the adhesiveness (resistance to a developer) of a cured product of the photosensitive resin composition. The acid value of the component (A) can be adjusted by a content of the structural units constituting the component (A) (for example, a structural unit derived from (meth)acrylic acid).

The acid value of the component (A) can be measured as follows. First, 1 g of a binder polymer for measurement of the acid value is precisely weighed out. 30 g of acetone is added to the precisely weighed binder polymer and the mixture was homogeneously dissolved. Next, an appropriate amount of phenolphthalein as an indicator is added to this solution and then titration is performed using a 0.1 N aqueous potassium hydroxide (KOH) solution. An amount of KOH in mg needed for neutralization of the acetone solution of the binder polymer to be measured is calculated to determine the acid value. In a case where a solution obtained by mixing the binder polymer with a synthetic solvent, a diluent solvent, or the like is used for measurement, the acid value is calculated by the following formula.

$$Acid value = 0.1 \times Vf \times 56.1 / ( Wp \times I / 100 )$$

In the formula, Vf represents a titer (mL) of the aqueous KOH solution, Wp represents a measured mass (g) of the solution containing the binder polymer, and I represents a measured proportion (% by mass) of a non-volatile content in the solution containing the binder polymer.

Furthermore, in a case where the binder polymer is blended in a state of being mixed with a volatile content such as a synthetic solvent and a diluent solvent, the acid value can also be measured after first heating for 1 to 4 hours at a temperature higher than the boiling point of the volatile content by 10° C. or higher in advance, before precise weighing, to remove the volatile content.

A weight-average molecular weight (Mw) of the component (A) may be 10000 or more, 20000 or more, or 25000 or more from the viewpoint of excellent adhesiveness of a cured product of the photosensitive resin composition (resistance to a developer), and may be 100000 or less, 80000 or less, or 60000 or less from the viewpoint of suitable developability. A degree of dispersion (Mw/Mn) of the component (A) may be, for example 1.0 or more, or 1.5 or more, and from the viewpoint of further improving adhesiveness and resolution, the Mw/Mn may be 3.0 or less, or 2.5 or less.

The weight-average molecular weight and the degree of dispersion of the binder polymer can be measured, for example, using a calibration curve of standard polystyrene by gel permeation chromatography (GPC). More specifically, the values can be measured under the conditions described in Examples. Incidentally, for compounds with low molecular weights, in a case where it is difficult to measure a weight-average molecular weight thereof using the above-mentioned measurement method, the molecular weight can be measured by another method to calculate an average of the values.

A content of the component (A) may be 20% by mass or more, 30% by mass or more, or 40% by mass or more from the viewpoint of excellent film formability, and may be 90% by mass or less, 80% by mass or less, or 65% by mass or less, from the viewpoint of more excellent sensitivity and resolution, each with respect to the total solid content of the photosensitive resin composition.

### (Component (B): Photopolymerizable Compound)

The photosensitive resin composition includes one kind or two or more kinds of the components (B). The component (B) is not particularly limited as long as it has at least one ethylenically unsaturated bond and is a photopolymerizable compound. The component (B) may include a polyfunctional monomer having two or more reactive groups that react with radicals. The component (B) may include a bisphenol A-type (meth)acrylate compound from the viewpoint of further improving the alkaline developability, the resolution, and the peeling characteristics after curing.

Examples of the bisphenol A-type (meth)acrylate compound include 2,2-bis(4-((meth)acryloxypolyethoxy)phenyl)propane (2,2-bis(4-((meth)acryloxypentaethoxy)phenyl)propane and the like), 2,2-bis(4-((meth)acryloxypolypropoxy)phenyl)propane, 2,2-bis(4-((meth)acryloxypolybutoxy)phenyl)propane, and 2,2-bis(4-((meth)acryloxypolyethoxypolypropxoy)phenyl)propane. The component (B) may include 2,2-bis(4-((meth)acryloxypolyethoxy)phenyl)propane (2,2-bis(4-((meth)acryloxypentaethoxy)phenyl)propane and the like) from the viewpoint of further improving the resolution and peeling characteristics.

Examples of a commercially available bisphenol A-type (meth)acrylate include BPE-200 (manufactured by SHIN-NAKAMURA CHEMICAL Co., Ltd., product name) as 2,2-bis(4-((meth)acryloxydipropoxy)phenyl)propane, BP-2EM (manufactured by Kyoeisha Chemical Co., Ltd., product name) as ethoxylated bisphenol A dimethacrylate, BPE-500 (manufactured by SHIN-NAKAMURA CHEMICAL Co., Ltd., product name) as 2,2-bis(4-(methacryloxypentaethoxy)phenyl)propane, and FA-321M (manufactured by Showa Denko Materials Co., Ltd., product name). These bisphenol A-type (meth)acrylates may be used alone or in combination of two or more kinds thereof.

A content of the bisphenol-type (meth)acrylate may be 40% to 98% by mass, 50% to 97% by mass, 60% to 95% by mass, or 70% to 90% by mass with respect to a total amount of the component (B). In a case where the content is 40% by mass or more, the resolution, the adhesiveness, and the repressibility of occurrence of resist footing are better, and in a case where the content is 98% by mass or less, the developing time is moderately shortened and development residues are more difficult to occur.

From the viewpoint of improving the flexibility of a cured product (cured film), the component (B) other than the bisphenol-type (meth)acrylate may further include at least one of polyalkylene glycol di(meth)acrylates having at least one of a (poly)oxyethylene chain and a (poly)oxypropylene chain in the molecule, and may further include a polyalkylene glycol di(meth)acrylate having both of a (poly)oxyethylene chain and a (poly)oxypropylene chain in the molecule. Examples of the polyalkylene glycol di(meth)acrylate include FA-023M (manufactured by Showa Denko Materials Co., Ltd., product name), FA-024M (manufactured by Showa Denko Materials Co., Ltd., product name), and NK Ester HEMA-9P (manufactured by SHIN-NAKAMURA CHEMICAL Co., Ltd., product name). These may be used alone or in combination of two or more kinds thereof.

A content of the polyalkylene glycol di(meth)acrylate may be 2% to 40% by mass, 3% to 30% by mass, or 5% to 20% by mass with respect to the total amount of the component (B).

As the component (B) other than those mentioned above, a nonylphenoxypolyethylene oxyacrylate, a phthalic acid-based compound, a polyol (meth)acrylate ester, an alkyl (meth)acrylate ester, or the like may be used. Among these, from the viewpoint of improving the resolution, the adhesiveness, the resist shape, and the peeling characteristics after curing in a well-balanced manner, the component (B) may include at least one selected from a nonylphenoxypolyethylene oxyacrylate and a phthalic acid-based compound. However, since these compounds have relatively low refractive indices, a content thereof may be 5% to 50% by mass, 5% to 40% by mass, or 10% to 30% by mass with respect to the total amount of the component (B) from the viewpoint of improving the resolution.

Examples of the nonylphenoxypolyethylene oxyacrylate include nonylphenoxytriethylene oxyacrylate, nonylphenoxytetraethylene oxyacrylate, nonylphenoxypentaethylene oxyacrylate, nonylphenoxyhexaethylene oxyacrylate, nonylphenoxyheptaethylene oxyacrylate, nonylphenoxyoctaethylene oxyacrylate, nonylphenoxynonaethylene oxyacrylate, nonylphenoxydecaethylene oxyacrylate, and nonylphenoxyundecaethylene oxyacrylate.

Examples of the phthalic acid-based compound include γ-chloro-β-hydroxypropyl-β′-(meth)acryloyloxyethyl-o-phthalate, β-hydroxyethyl-β′-(meth)acryloyloxyethyl-o-phthalate, and β-hydroxypropyl-β′-(meth)acryloyloxyethyl-o-phthalate, and among these, the phthalic acid-based compound may be γ-chloro-β-hydroxypropyl-β′-(meth)acryloyloxyethyl-o-phthalate. The γ-chloro-β-hydroxypropyl-β′-methacryloyloxyethyl-o-phthalate is commercially available as FA-MECH (manufactured by Showa Denko Materials Co., Ltd., product name).

From the viewpoint of improving the sensitivity and reducing footing trailing, the component (B) may include a polyol (meth)acrylate ester. Examples of the polyol (meth)acrylate ester include trimethylolpropane polyethoxy tri(meth)acrylate, trimethylolpropane polypropoxy tri(meth)acrylate, trimethylolpropane polybutoxy tri(meth)acrylate, trimethylolpropane polyethoxy polypropoxy tri(meth)acrylate, trimethylolethane polyethoxy tri(meth)acrylate, trimethylolethane polypropoxy tri(meth)acrylate, trimethylolethane polybutoxy tri(meth)acrylate, trimethylolethane polyethoxy polypropoxy tri(meth)acrylate, pentaerythritol polyethoxy tri(meth)acrylate, pentaerythritol polypropoxy tri(meth)acrylate, pentaerythritol polybutoxy tri(meth)acrylate, pentaerythritol polyethoxy polypropoxy tri(meth)acrylate, glyceryl polyethoxy tri(meth)acrylate, glyceryl polypropoxy tri(meth)acrylate, glyceryl polybutoxy tri(meth)acrylate, and glyceryl polyethoxy polypropoxy tri(meth)acrylate.

A content of the component (B) is preferably set to 20 to 60 parts by mass, more preferably set to 30 to 55 parts by mass, and still more preferably set to 35 to 50 parts by mass with respect to 100 parts by mass of a total amount of the component (A) and the component (B). In a case where the content of the component (B) is in this range, the photosensitivity and the film coatability in addition to the resolution, the adhesiveness, and the resist footing occurrence of the photosensitive resin composition are better.

### (Component (C): Photopolymerization Initiator)

The photosensitive resin composition includes one kind or two or more kinds of the components (C). Examples of the component (C) include hexaarylbiimidazole compounds; aromatic ketones such as benzophenone, 2-benzyl-2-dimethylamino-1-(4-morpholinophenyl)-1-butanone, 2-(dimethylamino)-2-[(4-methylphenyl)methyl]-1-[4-(4-morpholinyl)phenyl]-1-butanone, 4-(2-hydroxyethoxy)phenyl-2-(hydroxy-2-propyl)ketone, and 2-methyl-1-[4-(methylthio)phenyl]-2-morpholino-propanone-1; quinones such as alkyl anthraquinones; benzoin ether compounds such as benzoin alkyl ethers; benzoin compounds such as benzoin and alkyl benzoins; benzyl derivatives such as benzyl dimethyl ketal; bis(2,4,6-trimethylbenzoyl)-phenylphosphine oxide; bis(2,6-dimethylbenzoyl)-2,4,4-trimethyl-pentylphosphine oxide; and (2,4,6-trimethylbenzoyl)ethoxyphenylphosphine oxide.

The component (C) may include a hexaarylbiimidazole compound from the viewpoint of easily obtaining excellent sensitivity, resolution, and adhesiveness. The aryl group in the hexaarylbiimidazole compound may be a phenyl group or the like. The hydrogen atom bonded to the aryl group in the hexaarylbiimidazole compound may be substituted with a halogen atom (a chlorine atom or the like).

The hexaarylbiimidazole compound may be a 2,4,5-triarylimidazole dimer. Examples of the 2,4,5-triarylimidazole dimer include a 2-(o-chlorophenyl)-4,5-diphenylimidazole dimer, a 2-(o-chlorophenyl)-4,5-bis-(m-methoxyphenyl)imidazole dimer, and a 2-(p-methoxyphenyl)-4,5-diphenylimidazole dimer. From the viewpoint of easily obtaining excellent sensitivity, resolution, and adhesiveness, the hexaarylbiimidazole compound may include 2-(o-chlorophenyl)-4,5-diphenylimidazole dimer, and may include 2,2′-bis(2-chlorophenyl)-4,4′,5,5′-tetraphenyl-1,2′-biimidazole.

A content of the hexaarylbiimidazole compound may be 90% by mass or more, 95% by mass or more, or 99% by mass or more with respect to a total amount of the component (C) from the viewpoint of easily obtaining excellent sensitivity, resolution, and adhesiveness. The component (C) may consist of only the hexaarylbiimidazole compound.

A content of the component (C) may be 3.0 parts by mass or more, 4.0 parts by mass or more, 5.0 parts by mass or more, or 5.5 parts by mass or more, and may be 10 parts by mass or less, 9.0 parts by mass or less, 8.5 parts by mass or less, or 8.0 parts by mass or less, each with respect to 100 parts by mass of the total amount of the component (A) and the component (B), from the viewpoint of further improving the sensitivity, the resolution, and the adhesiveness and easily forming a resist pattern having a better resist shape. That is, the content of the component (C) may be 3.0 to 10 parts by mass, 4.0 to 9.0 parts by mass, 5.0 to 8.5 parts by mass, or 5.5 to 8.0 parts by mass with respect to 100 parts by mass of the total amount of the component (A) and the component (B). In particular, by setting the content of the component (C) 3.0 parts by mass or more, the adhesiveness can be further improved. Furthermore, by setting the content of the component (C) within the range, it is easy to adjust the absorbance of the photosensitive resin composition with respect to light at a wavelength of 365 nm per 1 μm of thickness within a range of more than 0.0041 and 0.0130 or less. In addition, by setting the content of the component (C) within the range, a photosensitive resin composition that is suitable for forming a resist pattern using a projection exposure system can be easily obtained.

### (Component (D): Sensitizer)

The photosensitive resin composition may include one kind or two or more kinds of the components (D). The component (D) may be a photosensitizer. Examples of the component (D) include a dialkylaminobenzophenone compound, a pyrazoline compound, an anthracene compound, a coumarin compound, a xanthone compound, a stilbene compound, and a triarylamine compound.

Examples of the pyrazoline compound include 1-phenyl-3-(4-methoxystyryl)-5-(4-methoxyphenyl)pyrazoline, 1-phenyl-3-(4-tert-butylstyryl)-5-(4-tert-butylphenyl)pyrazoline, and 1-phenyl-3-biphenyl-5-(4-tert-butylphenyl)pyrazoline. Examples of the anthracene compound include 9,10-dibutoxyanthracene and 9,10-diphenylanthracene. Examples of the coumarin compound include 3-benzoyl-7-diethylaminocoumarin, 7-diethylamino-4-methylcoumarin, 3,3′-carbonylbis(7-diethylaminocoumarin), and 2,3,6,7-tetrahydro-9-methyl-1H,5H,11H-[1] benzopyrano[6,7,8-ij]quinolizin-11-one.

From the viewpoint that the sensitivity, the resolution, and the adhesiveness can be further improved, and a resist pattern having a good resist shape is easily formed, the compound (D) may include at least one selected from the group consisting of a dialkylaminobenzophenone compound, a pyrazoline compound, an anthracene compound, and a coumarin compound, and may include at least one selected from the group consisting of 9,10-dibutoxy anthracene, 4,4′-bis(diethylamino) benzophenone, and 1-phenyl-3-(4-methoxystyryl)-5-(4-methoxyphenyl) pyrazoline. In addition, in a case of performing exposure at an exposure wavelength around 405 nm, the component (D) may include at least one selected from the group consisting of a pyrazoline compound and an anthracene compound from the viewpoint of further improving the sensitivity, the resolution, and the adhesiveness.

In a case where the component (D) is included in the photosensitive resin composition, a content thereof may be 0.01 parts by mass or more, or 0.02 parts by mass or more, and may be 1.5 parts by mass or less, 1.0 parts by mass or less, 0.8 parts by mass or less, 0.5 parts by mass or less, 0.2 parts by mass or less, 0.1 parts by mass or less, 0.05 parts by mass or less, or 0.03 parts by mass or less, each with respect to 100 parts by mass of the total amount of the component (A) and the component (B), from the viewpoint that the sensitivity, the resolution, and the adhesiveness can be further improved, and a resist pattern having a good resist shape is easily formed. In particular, by reducing the content of the component (D) to the upper limit value or less, there is a tendency that the resist shape can be better. Furthermore, in a case where the content of the component (D) is set to 0.03 parts by mass or less, the resistance of the resist to an acidic degreasing treatment before plating and the resistance of the resist to the plating solution tend to be further improved. In addition, by setting the content of the component (D) within the range, it is easy to adjust the absorbance of photosensitive resin composition with respect to light at a wavelength of 365 nm per 1 μm of thickness within a range of more than 0.0041 and 0.0130 or less. Furthermore, by setting the content of the component (D) within the range, a photosensitive resin composition that is suitable for forming a resist pattern using a projection exposure system can be easily obtained.

In a case where the photosensitive resin composition includes the component (D), a mass ratio of the content of the component (C) to the content of the component (D) (the content of the component (C)/the content of the component (D)) may be 40 or more, 50 or more, 80 or more, 100 or more, 150 or more, or 200 or more, and may be 500 or less, 400 or less, or 300 or less. By setting the mass ratio within the range, there is a tendency that the adhesiveness can be further improved. In addition, by setting the mass ratio within the range, it is easy to adjust the absorbance of photosensitive resin composition with respect to light at a wavelength of 365 nm per 1 μm of thickness within a range of more than 0.0041 and 0.0130 or less. Furthermore, by setting the mass ratio within the range, a photosensitive resin composition that is suitable for forming a resist pattern using a projection exposure system can be easily obtained.

### ((E) Component: Hydrogen Donor)

The photosensitive resin composition may include one kind or two or more kinds of the components (E). The component (E) is a hydrogen donor compound. By allowing the photosensitive resin composition to include the component (E), the sensitivity, the resolution, and the adhesiveness of the photosensitive resin composition are better, and a resist pattern having a better resist shape is easily formed.

Examples of the component (E) include bis[4-(dimethylamino)phenyl]methane, bis[4-(diethylamino)phenyl]methane, N-phenylglycine, and leuco crystal violet. These are used alone or in combination of two or more kinds thereof.

In a case where the component (E) is included in the photosensitive resin composition, a content thereof may be 0.3 parts by mass or more, 0.5 parts by mass or more, 0.55 parts by mass or more, 0.6 parts by mass or more, 0.7 parts by mass or more, or 0.75 parts by mass or more, and may be 2 parts by mass or less, 1.5 parts by mass or less, 1.0 parts by mass or less, or 0.9 parts by mass or less, each with respect to 100 parts by mass of the total amount of the component (A) and the component (B), from the viewpoint that the sensitivity, the resolution, and the adhesiveness can be further improved, and a resist pattern having a good resist shape is easily formed. In particular, by setting the content of the component (E) to 0.3 parts by mass or more, the adhesiveness can be further improved. Furthermore, by increasing the content of the component (E), the adhesiveness can be improved under conditions where the adhesiveness is deteriorated, such as low exposure conditions or development conditions that are longer than usual time. In addition, by setting the content of the component (E) to 2 parts by mass or less, the peeling time of the resist pattern can be further shortened.

In a case where the photosensitive resin composition includes the component (E), a total content of the component (C) and the component (E) may be 4.0 parts by mass or more, 5.0 parts by mass or more, or 6.0 parts by mass or more, and may be 12.0 parts by mass or less, 10.0 parts by mass or less, or 9.0 parts by mass or less, each with respect to 100 parts by mass of the total amount of the component (A) and the component (B), from the viewpoint that the sensitivity, the resolution, and the adhesiveness can be further improved, and a resist pattern having a good resist shape is easily formed. By setting the total amount of the component (C) and the component (E) to 4.0 parts by mass or more, the adhesiveness can be further improved. Furthermore, by setting the total amount of the component (C) and the component (E) within the range, it is easy to adjust the absorbance of the photosensitive resin composition with respect to light at a wavelength of 365 nm per 1 μm of thickness within a range of more than 0.0041 and 0.0130 or less. In addition, by setting the total amount of the component (C) and the component (E) within the range, a photosensitive resin composition that is suitable for forming a resist pattern using a projection exposure system can be easily obtained.

### (Heterocyclic Compound)

The photosensitive resin composition of the present embodiment may further contain a heterocyclic compound. This can further improve the resolution and the adhesiveness of the photosensitive resin composition Examples of the heterocyclic compound include 5-carboxybenzotriazole and 5-amino-1H-tetrazole. In particular, by allowing the photosensitive resin composition to contain a benzotriazole derivative such as 5-carboxybenzotriazole, the removability of the resist from the substrate can be improved. These compounds are used alone or in combination of two or more kinds thereof.

In a case where the heterocyclic compound is included in the photosensitive resin composition, a content thereof may be 0.01% to 5.0% by mass, 0.03% to 3.0% by mass, or 0.1% to 1.5% by mass with respect to the total solid content of the photosensitive resin composition. In a case where the content of the heterocyclic compound is 0.01% by mass or more, the resolution and the adhesiveness tend to be improved, and in a case where the content is 5.0% by mass or less, the development time and the peeling time of the photosensitive layer tend to be shortened.

### (Polymerization Inhibitor)

The photosensitive resin composition of the present embodiment may further contain a polymerization inhibitor. This makes the resolution of the photosensitive resin composition better. In addition, the temperature stability of the film is improved. Examples of the polymerization inhibitor include tert-butylcatechol and 2,2,6,6-tetramethyl-4-hydroxypiperidine-1-oxyl. In particular, in a case where the photosensitive resin composition contains 2,2,6,6-tetramethyl-4-hydroxypiperidine-1-oxyl (4-hydroxy-2,2,6,6-tetramethylpiperidine-N-oxyl), the lamination properties of the photosensitive layer including the photosensitive resin composition can be improved. These are used alone or in combination of two or more kinds thereof.

In a case where the polymerization inhibitor is included in the photosensitive resin composition, a content thereof may be 0.001% to 1.0% by mass, 0.005% to 0.5% by mass, or 0.01% to 0.1% by mass with respect to the total solid content of the photosensitive resin composition. In a case where the content of the polymerization inhibitor is 0.001% by mass or more, the resolution can be further improved, and in a case where the content is 1.0% by mass or less, the sensitivity can be further improved.

### (Other Components)

The photosensitive resin composition can further contain other components as necessary. Examples of the other components include a photopolymerizable compound (an oxetane compound or the like) having at least one cationic polymerizable cyclic ether group in the molecule, a cationic polymerization initiator, a tribromophenyl sulfone, a photocoloring agent, a thermal coloring inhibitor, a plasticizer (p-toluenesulfonamide or the like), a silane coupling agent, a pigment, a dye (malachite green, diamond green, or the like), a filler, a defoamer, a flame retardant, a stabilizer, an adhesiveness imparting agent, a leveling agent, a peeling accelerator, an antioxidant, a fragrance, an imaging agent, and a thermal crosslinking agent. These may be used alone or in combination of two or more kinds thereof. The contents of the other components may each be about 0.01% to 20% by mass.

In order to improve the handleability of the photosensitive resin composition or adjust the viscosity and the storage stability, the photosensitive resin composition can contain at least one kind of organic solvents. As the organic solvent, an organic solvent to be generally used can be used without particular limitation. Examples of the organic solvent include methanol, ethanol, acetone, methyl ethyl ketone, methyl cellosolve, ethyl cellosolve, toluene, N,N-dimethylformamide, propylene glycol monomethyl ether, and mixed solvents thereof. For example, the component (A), the component (B), and the component (C) are dissolved in an organic solvent and then the resultant solution can be used as a solution having a solid content of about 30% to 60% by mass (hereinafter referred to as a “coating liquid”). Furthermore, the solid content means remaining components obtained by removing a volatile content from the solution of the photosensitive resin composition.

### (Absorbance)

The photosensitive resin composition of the present embodiment has an absorbance for light with a wavelength of 365 nm per 1 μm of thickness of more than 0.0041 and 0.0130 or less. By setting the absorbance to more than 0.0041, the sensitivity, the resolution, and the adhesiveness can be improved. By setting the absorbance to 0.0130 or less, the sensitivity, the resolution, and the adhesiveness can be improved, and at the same time, it is possible to form a resist pattern having a good resist shape. From the viewpoint of further improving the sensitivity, resolution, and adhesiveness, the absorbance may be 0.0045 or more, 0.0050 or more, 0.0055 or more, or 0.0060 or more, and from the viewpoint of further improving the sensitivity, resolution, and adhesiveness and improving the resist shape, the absorbance may be 0.0120 or less, 0.0110 or less, 0.0100 or less, 0.0090 or less, or 0.0080 or less.

The absorbance of the photosensitive resin composition can be appropriately adjusted depending on the types and the contents of the (B) photopolymerizable compound, the (C) photopolymerization initiator, the (D) sensitizer, the (E) hydrogen donor, and the other components, each described above.

The absorbance of the photosensitive resin composition can be measured by forming a photosensitive layer by forming a film from the photosensitive resin composition, and measuring the absorbance of this photosensitive layer with respect to light at a wavelength of 365 nm using, for example, an ultraviolet-visible spectrophotometer such as a U-3310 spectrophotometer (manufactured by Hitachi High-Tech Science Corporation). The absorbance per 1 μm of thickness of the photosensitive resin composition can be determined by dividing the absorbance measured for the photosensitive layer by the thickness of the photosensitive layer (unit: μm).

### [Photosensitive Element]

A photosensitive element of the present embodiment includes a support and a photosensitive layer including the photosensitive resin composition formed on the support. In a case of using the photosensitive element of the present embodiment, the photosensitive layer may be laminated on a substrate and then exposed without peeling the support. The photosensitive element may be provided with a protective layer on the surface of the photosensitive layer opposite the support. Incidentally, the photosensitive element may also include an intermediate layer between the support and the photosensitive layer.

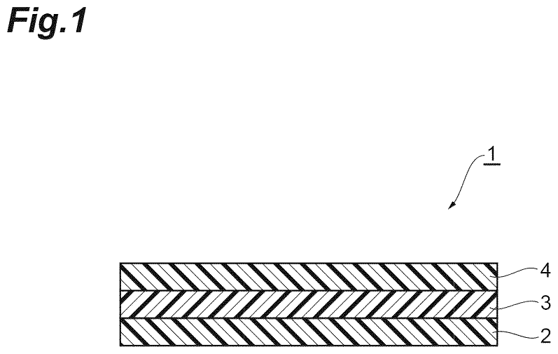

FIG. 1 is a schematic cross-sectional view of a photosensitive element according to one embodiment. As shown in FIG. 1, a photosensitive element 1 includes a support 2, a photosensitive layer 3 provided on the support 2, and a protective layer 4 provided on a side of the photosensitive layer 3 opposite the support 2.

### (Support 2)

As the support, a polymer film (support film) having heat resistance and solvent resistance of polyesters such as polyethylene terephthalate (PET), polyolefins such as polypropylene and polyethylene, or the like can be used. Among those, the support may be the PET film from the viewpoint that it is easily available and has excellent handleability (in particular, heat resistance, a heat shrinkage rate, and a breaking strength) in the production step.

A haze of the support may be 0.01% to 1.0%, or 0.01% to 0.5%. In a case where the haze of the support is 0.01% or more, the support itself tends to be easier to produce, and in a case where the haze is 1.0% or less, micro-defects that may occur in the resist pattern tend to be reduced. Here, the “haze” means cloudiness. The haze in the present disclosure refers to a value measured using a commercially available haze meter (turbidimeter) in accordance with the method specified in JIS K 7105. The haze can be measured, for example, using a commercially available turbidimeter such as NDH-5000 (manufactured by NIPPON DENSHOKU INDUSTRIES CO., LTD.).

The number of particles and the like with a diameter of 5 μm or more included in the support is 5 particles/mm² or less, and the support may contain particles. This improves the slipperiness of the support surface, and at the same time, suppresses light scattering during exposure in a well-balanced manner, thereby improving the resolution and the adhesiveness. An average particle diameter of the particles may be 5 μm or less, 1 μm or less, or 0.1 μm or less. Incidentally, the lower limit value of the average particle diameter is not particularly limited, but may be 0.001 μm or more.

Examples of a product that is commercially available as such a support include “QS48” (Toray Industries, Inc.), “FB40” (Toray Industries, Inc.), “FS-31” (Toray Industries, Inc.), and “HTF-01” (Teijin Film Solutions Co., Ltd.), each of which is a three-layer structure biaxially oriented PET film containing particles on an outermost layer, and “A-1517” (TOYOBO CO., LTD.) and “R705G” (Mitsubishi Chemical Corporation), each of which is a two-layer structure biaxially oriented PET film having a layer containing particles on one surface.

A thickness of the support may be 1 to 100 μm, 5 to 50 μm, or 5 to 30 μm. In a case where the thickness is 1 μm or more, the support can be suppressed from being torn when the support is peeled, and in a case where the thickness is 100 μm or less, a decrease in resolution can be suppressed.

### (Intermediate Layer)

The photosensitive element may further include an intermediate layer (not shown) between the support and the photosensitive layer. The intermediate layer may be a barrier layer having gas barrier properties. In a case of including such an intermediate layer (barrier layer), it is possible to reduce adverse effects on the photosensitive layer caused by oxygen incorporation in a case where the support is peeled and exposed. The intermediate layer may be a layer containing a water-soluble resin. Furthermore, the intermediate layer may also be a layer containing a water-soluble resin and an alcohol having 3 or more carbon atoms. In this case, even with the intermediate layer not containing a peeling accelerator, the support can be peeled smoothly from the intermediate layer, and therefore, in a case where the photosensitive layer is exposed through the intermediate layer after peeling the support, a deterioration of the resolution of a resist pattern thus formed can be suppressed.

The intermediate layer may be a layer formed using the resin composition for forming an intermediate layer of the present embodiment described later. The resin composition for forming an intermediate layer of the present embodiment may contain a water-soluble resin, an alcohol having 3 or more carbon atoms, and water. Furthermore, the intermediate layer may also be water-soluble and may be soluble in a developer. In addition, from the viewpoint of further improving the gas barrier properties of the intermediate layer, an adhesive force between the support and the intermediate layer may be smaller than an adhesive force between the intermediate layer and the photosensitive layer. That is, it can be said that in a case where the support is peeled from the photosensitive element, unintended peeling between the intermediate layer and the photosensitive layer is suppressed.

Here, the “water-soluble resin” means a resin having a solubility of 5 g/100 mL-hexane or less in 100 mL of hexane at 25° C. This solubility can be calculated by mixing hexane at 25° C. with a dried water-soluble resin, and examining the presence or the absence of white turbidity. Specifically, a sample 1 obtained by placing a mixed liquid of A (g) of the dried water-soluble resin and hexane (100 mL−A) in a colorless transparent glass container with a ground glass joint, and a sample 2 obtained by placing only 100 mL of hexane in another colorless transparent glass container with a ground glass joint are each prepared. Then, the samples in the glass containers are shaken thoroughly and then it is confirmed that bubbles have disappeared. Immediately after the confirmation both the containers are placed side by side in diffused daylight or equivalent light, and the liquid state of the sample 1 and the liquid state of the sample 2 are compared. Through the comparison between the sample 1 and the sample 2, the addition amount A (g) in a case where the sample 1 begins to be observed to become cloudier or in a case where floating of the solid content begins to be observed is defined as the solubility of the water-soluble resin in 100 mL of hexane at 25° C.

Examples of the water-soluble resin include polyvinyl alcohol, polyvinylpyrrolidone, and water-soluble polyimides. From the viewpoint of further improving the gas barrier properties of the intermediate layer and further suppressing the deactivation of radicals generated by the active light rays used for exposure, the water-soluble resin may include polyvinyl alcohol. Polyvinyl alcohol can be obtained, for example, by saponifying polyvinyl acetate obtained by polymerizing vinyl acetate. A degree of saponification of polyvinyl alcohol used in the present embodiment may be 50% by mole or more, 70% by mole or more, or 80% by mole or more. Furthermore, the upper limit of the degree of saponification is 100% by mole. By including polyvinyl alcohol with a degree of saponification of 50% by mole or more, there is a tendency that the gas barrier properties of the intermediate layer are further improved and the resolution of the formed resist pattern can be further improved. Furthermore, in the present specification, the “degree of saponification” refers to a value measured in accordance with JIS K 6726 (1994) (Testing Method for Polyvinyl Alcohol) as specified in the Japanese Industrial Standards.

Two or more of the polyvinyl alcohols having different degrees of saponification, viscosities, degrees of polymerization, modification types, and the like may be used in combination. Furthermore, an average degree of polymerization of polyvinyl alcohol may be 300 to 5000, 300 to 3500, or 300 to 2000. Furthermore, the water-soluble resins may be used alone or in combination of two or more kinds thereof. The water-soluble resin may include, for example, polyvinyl alcohol and polyvinylpyrrolidone. In this case, a mass ratio of polyvinyl alcohol to polyvinylpyrrolidone (PVA:PVP) may be 40:60 to 90:10, 50:50 to 90:10, or 60:40 to 90:10.

A content of the water-soluble resin in the resin composition for forming an intermediate layer of the present embodiment may be 50 to 300 parts by mass, 60 to 250 parts by mass, 70 to 200 parts by mass, 80 to 150 parts by mass, or 80 to 125 parts by mass with respect to 500 parts by mass of water from the viewpoint of improving the gas barrier properties.

The alcohols having 3 or more carbon atoms may be monohydric alcohols or polyhydric alcohols (excluding plasticizers of polyhydric alcohol compounds described later). The number of carbon atoms in the alcohol having 3 or more carbon atoms means a sum of the carbon numbers in the alcohols, and may be 10 or less, 8 or less, 7 or less, 6 or less, or 5 or less. The alcohols having 3 or more carbon atoms may contain at least one selected from the group consisting of compounds represented by the following Chemical Formulae (1) to (3) and compounds represented by the following General Formula (4). By containing such an alcohol having 3 or more carbon atoms, the peelability between the intermediate layer and the support can be further improved.

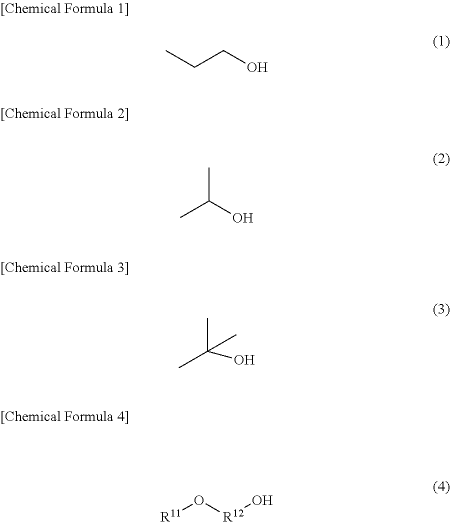

In General Formula (4), R¹¹ represents an alkyl group and R¹² represents an alkylene group. Furthermore, a sum of the numbers of carbon atoms of the group of R¹¹ and the group of R¹² is 3 or more. In addition, the sum of numbers of carbon atoms of the group of R¹¹ and the group of R¹² may be 10 or less, 8 or less, 7 or less, 6 or less, or 5 or less from the viewpoint of further improving the affinity with water. The alkyl group represented by R¹¹ may be an alkyl group having 1 to 4 carbon atoms, and the alkylene group represented by R¹² may be an alkylene group having 1 to 3 carbon atoms. Furthermore, the alkyl group represented by R¹¹ and the alkylene group represented by R¹² may or may not each have a substituent. In a case of having the substituent, the numbers of carbon atoms of the group of R¹¹ and the group of R¹² each include the number of carbon atoms of the substituent. In addition, the alcohol having 3 or more carbon atoms represented by General Formula (4) may be also 2-butoxyethanol or 1-methoxy-2-propanol.

The alcohols having 3 or more carbon atoms may be used alone or in combinations of two or more kinds thereof. Furthermore, the solubility of the alcohols having 3 or more carbon atoms in water at 20° C. may be 300 mL/100 mL-water or more, 500 mL/100 mL-water or more, or 1000 mL/100 mL-water or more from the viewpoint of further suppressing layer separation of the intermediate layer.

“The solubility of the alcohol having 3 or more carbon atoms in water at 20° C.” in the present specification is calculated by mixing the alcohol with water at 20° C., and examining the presence or absence of white turbidity. Specifically, a sample 3 obtained by placing a mixed liquid of A mL of the alcohol and (100−A) mL of water in a colorless transparent glass container with a ground glass joint, and a sample 4 obtained by placing only 100 mL of water in another colorless transparent glass container with a ground glass joint are each prepared. Next, each of the sample 3 and the sample 4 in the glass container is shaken thoroughly and then it is confirmed that bubbles have disappeared. Immediately after the confirmation, both the containers are placed side by side in diffused daylight or equivalent light, and the condition of the liquid of the sample 3 and the condition of the liquid of the sample 4 are compared. Through the comparison between the sample 3 and the sample 4, the addition amount A mL of the alcohol in a case where the sample 3 is observed to be cloudier is defined as a solubility of the alcohol in water at 20° C.

A content of the alcohol having 3 or more carbon atoms in the resin composition for forming an intermediate layer of the present embodiment may be 100 to 500 parts by mass, 110 to 480 parts by mass, 120 to 460 parts by mass, 125 to 440 parts by mass, 125 to 420 parts by mass, or 125 to 400 parts by mass with respect to 500 parts by mass of water. In a case where the content is 100 parts by mass or more, the peelability between the intermediate layer to be formed and a support tends to be improved, and in a case where the content is 500 parts by mass or less, the solubility of the water-soluble resin is improved and the intermediate layer tends to be easily formed.

The content of the alcohol having 3 or more carbon atoms in the intermediate layer of the present embodiment may be more than 0% by mass and 2.0% by mass or less, 0.001% to 2.0% by mass, or 0.005% to 1.0% by mass with respect to on a total amount of the intermediate layer (a total amount of the solid content of the resin composition for forming an intermediate layer, which forms the intermediate layer). In a case where the content is 2.0% by mass or less, the diffusion of the alcohol in a later step tends to be suppressed, in a case where the content is more than 0% by mass, the peelability between the intermediate layer and the support tends to be improved, and in a case where the content is 0.001% by mass or more, the peelability between the intermediate layer and the support tends to be further improved.

The resin composition for forming an intermediate layer of the present embodiment may contain an alcohol having less than 3 carbon atoms. In a case where the alcohol having less than 3 carbon atoms is contained in the resin composition for an intermediate layer, a content thereof may be 125 to 375 parts by mass, or 150 to 325 parts by mass with respect to 500 parts by mass of water. In a case where the content is 125 parts by mass or more, the solubility of the water-soluble resin is improved, and the intermediate layer tends to be formed easily, and in a case where the content is 375 parts by mass or less, the peelability between the barrier layer thus formed and the support tends to be improved. Furthermore, from the viewpoint of improving the peelability between the intermediate layer and the support, the content of the alcohol having less than 3 carbon atoms in the intermediate layer of the present embodiment may be 0.1% to 10% by mass with respect to a total amount of alcohols in the intermediate layer, or may be 0.1 to 10 parts by mass with respect to 100 parts by mass of the total amount of the alcohols having 3 or more carbon atoms in the intermediate layer.

Moreover, the resin composition for forming an intermediate layer of the present embodiment may contain a known additive such as a plasticizer and a surfactant within a range not impeding the effects of the present disclosure. In addition, the resin composition may contain a peeling accelerator within a range not impeding the effects of the present disclosure.

As the plasticizer, for example, a polyhydric alcohol compound may be contained from the viewpoint of improving stretchability. Examples of the plasticizer include glycerols such as glycerol, diglycerol, and triglycerol, (poly)alkylene glycols such as ethylene glycol, diethylene glycol, triethylene glycol, tetraethylene glycol, polyethylene glycol, propylene glycol, dipropylene glycol, and polypropylene glycol, and trimethylolpropane. These plasticizers may be used alone or in combinations of two or more kinds thereof.

The intermediate layer in the photosensitive element of the present embodiment can be formed, for example, by applying the resin composition for forming an intermediate layer of the present embodiment on a support, and drying the same.

A thickness of the intermediate layer is not particularly limited. The thickness of the intermediate layer may be 12 μm or less, 10 μm or less, 8 μm or less, 7 μm or less, or 6 μm or less from the viewpoint of easy removal of the intermediate layer. Furthermore, the thickness of the intermediate layer may be 1.0 μm or more, 1.5 μm or more, 2 μm or more, 3 μm or more, or 4 μm or more from the viewpoints of easy formation of an intermediate layer and the resolution.

Moreover, the intermediate layer in the present embodiment may have photosensitivity, but the photosensitivity is lower than that of the photosensitive layer. Incidentally, the intermediate layer may not have photosensitivity. In a case where the intermediate layer does not have photosensitivity, the photosensitivity stability of the photosensitive layer tends to be improved. In addition, the “photosensitivity” means that, for example, in a case where the photosensitive layer is exposed, subjected to a heating treatment after the exposure as necessary, and then developed using a developer to remove the uncured area of the photosensitive layer, a resist pattern can be formed.

### (Photosensitive Layer 3)

The photosensitive layer 3 is a layer formed using the above-described photosensitive resin composition. A thickness of the photosensitive layer 3 after drying (after volatilizing an organic solvent in a case where the photosensitive resin composition contains the organic solvent) can be appropriately selected depending on the application, but the thickness after drying may be 1 to 100 μm, 3 to 50 μm, 5 to 40 μm, or 10 to 30 μm. In a case where the thickness of the photosensitive layer is 1 μm or more, the industrial coating is easier and the productivity is improved, and in a case where the thickness is 100 μm or less, the adhesiveness and the resolution are further improved.

### (Protective Layer 4)

The photosensitive element may be a polymer film having heat resistance and solvent resistance. As the protective layer, a film in which the adhesive force between the photosensitive layer and the protective layer is smaller than the adhesive force between the photosensitive layer and the support may be used, and a film with low fisheyes may also be used. Specific examples thereof include the protective layers that can be used as the above-described support. From the viewpoint of the peelability from the photosensitive layer, the protective layer may be a polyethylene film. A thickness of the protective layer varies depending on the application, but may be about 1 to 100 μm.

### [Method for Producing Photosensitive Element]

The photosensitive element can be produced, for example, as follows. The photosensitive element can be produced by a production method including preparing a coating liquid of the above-described photosensitive resin composition, applying the coating liquid onto a support to form a coating layer, and drying the coating layer to form a photosensitive layer. The application of the coating liquid on the support can be performed, for example, by a known method such as roll coating, comma coating, gravure coating, air knife coating, die coating, and bar coating.

The drying of the coating layer is not particularly limited as long as at least a part of the organic solvent can be removed from the coating layer. The drying may be performed, for example, at 70 to 150° C. for about 5 to 30 minutes. After the drying, the amount of the organic solvent remaining in the photosensitive layer may be 2% by mass or less from the viewpoint of preventing the diffusion of the organic solvent in the subsequent step.

Since the photosensitive layer in the photosensitive element is a layer formed using the photosensitive resin composition, the absorbance with respect to light at a wavelength of 365 nm per 1 μm of thickness may be more than 0.0041 and 0.0130 or less. In a case where the absorbance is more than 0.0041, the sensitivity, the resolution, and the adhesiveness can be improved. In a case where the absorbance is 0.0130 or less, the sensitivity, the resolution, and the adhesiveness can be improved, and a resist pattern having a good resist shape can also be formed. From the viewpoint of further improving the sensitivity, the resolution, and the adhesiveness, the absorbance may be 0.0045 or more, 0.0050 or more, 0.0055 or more, or 0.0060 or more, and from the viewpoint of further improving the sensitivity, the resolution, and the adhesiveness, and making the resist shape better, the absorbance may be 0.0120 or less, 0.0110 or less, 0.0100 or less, 0.0090 or less, or 0.0080 or less.

The photosensitive element can be suitably used, for example, in a method for forming a resist pattern described later. Above all, from the viewpoint of the resolution, the photosensitive element is suitable for application to a method for producing a conductor pattern by a plating treatment. In addition, the photosensitive element can be suitably used in formation of a resist pattern using a projection exposure system.

### [Method for Forming Resist Pattern]

A method for forming a resist pattern of the present embodiment includes a photosensitive layer forming step of laminating a photosensitive layer including the photosensitive resin composition or the photosensitive layer of the photosensitive element on a substrate, an exposure step of irradiating a predetermined portion of the photosensitive layer with active light rays to form a photocured area, and a development step of removing an area other than the predetermined portion of the photosensitive layer from the substrate. The method for forming a resist pattern may include other steps as necessary. Furthermore, the resist pattern can be said to be a photocured product pattern or a relief pattern of the photosensitive resin composition. In addition, the method for forming a resist pattern can be said to be a method for producing a substrate with a resist pattern.

### (Photosensitive Layer Forming Step)

As a method for forming the photosensitive layer on a substrate, for example, the photosensitive resin composition may be applied and dried, or after the protective layer is removed from photosensitive element, the photosensitive layer of the photosensitive element may be pressure-bonded on the substrate during the heating of the photosensitive layer. In a case of using the photosensitive element, a laminate including the substrate, the photosensitive layer, and the support, which are laminated in this order, can be obtained. Furthermore, in a case where the photosensitive element includes an intermediate layer, it is in a state where the intermediate layer is arranged between the photosensitive layer and the support. The substrate is not particularly limited, and a substrate for circuit formation, including an insulation layer and a conductor layer formed on the insulation layer, a metal base material for production of a metal mask, a die pad (a base material for a lead frame) such as an alloy base material, or the like is usually used.

A surface roughness (Sa) of the substrate may be 1 to 200 nm, or 3 to 100 nm from the viewpoint of further improving the resolution. In a case where the Sa is 3 to 100 nm, halation due to irregularities on the substrate surface can be suppressed and the resolution is further improved.

In a case of using the photosensitive element, the heating of the photosensitive layer and/or the substrate during the pressure bonding may be performed at a temperature of 70 to 130° C. The pressure bonding may be performed at a pressure of about 0.1 to 1.0 MPa (about 1 to 10 kgf/cm²), but these conditions are appropriately selected as necessary. Furthermore, in a case where the photosensitive layer is heated to 70 to 130° C., it is not necessary to preheat the substrate in advance, but the substrate can also be preheated in order to further improve the adhesiveness and the followability.

### (Exposure Step)

In the exposure step, at least a part of the photosensitive layer formed on the substrate is irradiated with active light rays to photocure the area irradiated with the active light rays, thereby forming a latent image. At this time, in a case where the support present on the photosensitive layer is transparent to the active light rays, the photosensitive layer can be irradiated with the active light rays through the support, whereas in a case where the support blocks the active light rays, the photosensitive layer is irradiated with the active light rays after the support is removed. In addition, in a case where an intermediate layer is provided between the photosensitive layer and the support, only the support is removed and the intermediate layer is left on the photosensitive layer. In this case, the photosensitive layer is exposed with the active light rays through the intermediate layer.

Examples of the exposure method include a method of performing imagewise irradiation with active light rays through a negative or positive mask pattern called artwork (mask exposure method). Furthermore, a method of performing imagewise irradiation with active light rays by a projection exposure method may also be adopted. In the method of forming a resist pattern according to the present embodiment, it is preferable to perform irradiation with the active light rays by a projection exposure method to form a photocured area. In addition, as the exposure method, a contact exposure method, a direct writing exposure method, or the like may be used.

Known light sources can be used as a light source for the active light rays and, for example, a carbon arc lamp, a mercury vapor arc lamp, a high-pressure mercury lamp, an ultrahigh pressure mercury lamp, a xenon lamp, a gas laser such as an argon laser, a solid-state laser such as a YAG laser, a semiconductor laser, LED, or the like, which effectively emits ultraviolet rays or visible light, is used. The wavelength of the active light rays may be in a range of 340 nm to 430 nm or in a range of 355 nm to 375 nm.

In addition, a post-exposure bake (PEB) may be performed using a hot plate, a dryer, or the like after the exposure from the viewpoint of improving the pattern formability. The heating conditions are not particularly limited, but the PEB may be performed at a temperature of 60 to 120° C. or 70 to 110° C. for 15 seconds to 5 minutes or 30 seconds to 3 minutes.

### (Development Step)

In the development step, at least a part of the photosensitive layer other than the photocured area is removed from the substrate to form a resist pattern on the substrate. In a case where the support is present on the photosensitive layer, the support is removed and then an area (also called an unexposed area) other than the photocured area is removed (developed). In a case where an intermediate layer exists and is water-soluble, the intermediate layer may be removed by washing with water, and then an uncured area other than the photocured area may be removed with a developer. In a case where the intermediate layer is soluble in the developer, the intermediate layer may be removed with the developer together with the uncured area other than the photocured area. The development method includes wet development and dry development, but the wet development is widely used.

In a case of the wet development, development is performed by a known development method using a developer corresponding to the photosensitive resin composition. Examples of the development method include methods using a dipping system, a paddling system, a spraying system, brushing, slapping, scrubbing, shaking immersion, or the like, and from the viewpoint of improving the resolution, a high-pressure spraying system may be used. A combination of two or more of these methods may be used to perform the development.

The configuration of the developer is appropriately selected depending on the configuration of the photosensitive resin composition. Examples of the developer include an alkaline aqueous solution and an organic solvent developer.

From the viewpoint of being safe and stable and having good handleability, an alkaline aqueous solution may be used as the developer. As a base of the alkaline aqueous solution, alkali hydroxides such as hydroxides of lithium, sodium, or potassium; alkali carbonates such as carbonates or bicarbonates of lithium, sodium, potassium, or ammonium; alkali metal phosphates such as potassium phosphate and sodium phosphate; alkali metal pyrophosphates such as sodium pyrophosphate and potassium pyrophosphate; borax, sodium metasilicate, tetramethylammonium hydroxide, ethanolamine, ethylenediamine, diethylene triamine, 2-amino-2-hydroxymethyl-1,3-propanediol, 1,3-diaminopropanol-2, morpholine, or the like is used.

As the alkaline aqueous solution used for development, a 0.1% to 5% by mass dilute solution of sodium carbonate, a 0.1% to 5% by mass dilute solution of potassium carbonate, a 0.1% to 5% by mass dilute solution of sodium hydroxide, a 0.1% to 5% by mass dilute solution of sodium tetraborate, or the like can be used. A pH of the alkaline aqueous solution used for development may be set in a range of 9 to 11, and a temperature thereof can be adjusted according to the alkali developability of the photosensitive layer.

For example, a surfactant, an antifoaming agent, a small amount of an organic solvent for accelerating development, or the like may be incorporated into the alkaline aqueous solution. Furthermore, examples of the organic solvent used for the alkaline aqueous solution include acetone, ethyl acetate, alkoxyethanol having an alkoxy group having 1 to 4 carbon atoms, ethyl alcohol, isopropyl alcohol, butyl alcohol, diethylene glycol monomethyl ether, diethylene glycol monoethyl ether, and diethylene glycol monobutyl ether.

Examples of the organic solvent used for the organic solvent developer include 1,1,1-trichloroethane, N-methylpyrrolidone, N,N-dimethylformamide, cyclohexanone, methyl isobutyl ketone, and γ-butyrolactone. The organic solvent developer may be prepared by adding water to these organic solvents within a range of 1% to 20% by mass for anti-flammability.

The method for forming a resist pattern in the present embodiment may include a step of removing the uncured area in the development step, and then further curing the resist pattern by heating at about 60 to 250° C. or exposing at about 0.2 to 10 J/cm², as necessary.

### [Method for Producing Semiconductor Package Substrate or Printed Wiring Board]

A method for producing a semiconductor package substrate or printed wiring board of the present embodiment includes a step of subjecting a substrate having a resist pattern formed by the method for forming a resist pattern to a plating treatment or an etching treatment to form a conductor pattern. The method for producing a semiconductor package substrate or printed wiring board may include other steps such as a resist pattern removing step, as necessary.

In the plating treatment, a conductor layer provided on the substrate is subjected to the plating treatment using the resist pattern formed on the substrate as a mask. After the plating treatment, a conductor pattern may be formed by removing the resist by the removal of the resist pattern which will be described later, and further etching the conductor layer covered by the resist.

The plating treatment method may be either an electrolytic plating treatment or an electroless plating treatment. In the etching treatment, the conductor layer formed on the substrate is removed by etching, using the resist pattern formed on the substrate as a mask, to form a conductor pattern. The etching treatment method is appropriately selected depending on the conductor layer to be removed. Examples of the etching liquid include a cupric chloride solution, a ferric chloride solution, an alkali etching solution, and a hydrogen peroxide-based etching liquid.

After the etching treatment or the plating treatment, the resist pattern on the substrate may be removed. The resist pattern can be removed by peeling, for example, with an aqueous solution more strongly alkaline than the alkaline aqueous solution used in the development step. For example, an amine-based peeling solution (15% by volume R-100S+8% by volume aqueous R-101 solution (manufactured by MITSUBISHI GAS CHEMICAL COMPANY, INC.)) is used as the strongly alkaline aqueous solution. In addition, a 1%- to 10%-by-mass aqueous sodium hydroxide solution, a 1%- to 10%-by-mass aqueous potassium hydroxide solution, or the like may be used as the strong alkaline aqueous solution.

In a case where the resist pattern is removed after performing the plating treatment, a desired semiconductor package substrate or printed wiring board can be produced by further subjecting the conductor layer covered by the resist to the etching treatment to form a conductor pattern. The etching treatment method at this time is appropriately selected depending on the conductor layer to be removed. For example, the above-described etching liquid can be applied.

The method for producing a semiconductor package substrate or printed wiring board according to the present embodiment can be applied not only to production of a single-layer semiconductor package substrate or printed wiring board but also to production of a multilayer semiconductor package substrate or printed wiring board, and can also be applied to production of a semiconductor package substrate or printed wiring board having small-diameter through-holes, and the like.

### EXAMPLES

Hereinafter, the present disclosure will be more specifically described with reference to Examples, but is not limited to these Examples.

### <Synthesis of Binder Polymer A-1>

270 g of methacrylic acid, 500 g of styrene, 200 g of benzyl methacrylate, and 30 g of 2-hydroxyethyl methacrylate, which are polymerizable monomers, and 9 g of azobisisobutyronitrile were mixed to prepare a solution (a). In addition, 1.4 g of azobisisobutyronitrile was mixed with a mixed liquid of 160 g of 1-methoxy-2-propanol and 120 g of toluene to prepare a solution (b). A mixed liquid of 450 g of 1-methoxy-2-propanol and 380 g of toluene was placed in a flask equipped with a stirrer, a reflux condenser, a thermometer, a dropping funnel, and a nitrogen gas inlet tube, and the mixture was stirred while blowing nitrogen gas into the flask and heated to 80° C. The solution (a) was dropped into the mixed liquid in the flask at a constant dropping rate over 4 hours, and then stirred at 80° C. for 2 hours. Next, the solution (b) was dropped into the solution in the flask at a constant dropping rate over 10 minutes, and then the solution in the flask was stirred at 80° C. for 3 hours. Furthermore, the solution in the flask was heated to 90° C. over 30 minutes and kept at 90° C. for 6 hours, the stirring was then stopped, and the solution was cooled to room temperature (25° C.) to obtain a solution of a binder polymer A-1. The non-volatile content (solid content) of the solution of the binder polymer A-1 was 49% by mass. The weight-average molecular weight (Mw) of the binder polymer A-1 is shown in Table 1.

### <Synthesis of Binder Polymer A-2>

270 g of methacrylic acid, 450 g of styrene, 230 g of benzyl methacrylate, and 50 g of methyl methacrylate, which are polymerizable monomers, and 6 g of azobisisobutyronitrile were mixed to prepare a solution (a). In addition, 1.4 g of azobisisobutyronitrile was mixed with a mixed liquid of 180 g of 1-methoxy-2-propanol and 150 g of toluene to prepare a solution (b). A mixed liquid of 400 g of 1-methoxy-2-propanol and 340 g of toluene was put into a flask equipped with a stirrer, a reflux condenser, a thermometer, a dropping funnel, and a nitrogen gas inlet tube, the mixture was stirred while blowing nitrogen gas into the flask and heated to 80° C. The solution (a) was dropped into the mixed liquid in the flask at a constant dropping rate over 4 hours, and then stirred at 80° C. for 2 hours. Next, the solution (b) was dropped into the solution in the flask at a constant dropping rate over 10 minutes, and then the solution in the flask was stirred at 80° C. for 3 hours. Furthermore, the solution in the flask was heated to 90° C. over 30 minutes and kept at 90° C. for 6 hours, the stirring was then stopped, and the solution was cooled to room temperature (25° C.) to obtain a solution of a binder polymer A-2. The non-volatile content (solid content) of the solution of the binder polymer A-2 was 49% by mass. The weight-average molecular weight (Mw) of the binder polymer A-2 is shown in Table 1.

Moreover, the weight-average molecular weight was measured by gel permeation chromatography (GPC) and calculated using a calibration curve of standard polystyrene. The GPC conditions were as shown below.

### (GPC Conditions)

Column: Gelpack GL-R440, Gelpack GL-R450, and Gelpack GL-R400M (all manufactured by Showa Denko Materials Co., Ltd.) in connection
Eluent: Tetrahydrofuran
Measurement temperature: 40° C.
Flow rate: 2.05 mL/min
Detector: Hitachi L-2490 type RI (manufactured by Hitachi, Ltd.)

TABLE 1

Binder polymer

| | A-1 | A-2 |
|---|---|---|
| Methacrylic acid | 27 | 27 |
| Styrene | 50 | 45 |
| Benzyl methacrylate | 20 | 23 |
| 2-Hydroxyethyl methacrylate | 3 | — |
| Methyl methacrylate | — | 5 |
| Weight-average molecular weight | 35000 | 50000 |

### Examples 1 to 14 and Comparative Examples 1 to 5

### <Preparation of Photosensitive Resin Composition>

In the blending amounts (parts by mass) shown in Tables 2 to 4 below, each of photosensitive resin compositions of Examples and Comparative Examples was prepared by mixing (A) a binder polymer with (B) a photopolymerizable compound, (C) a photopolymerization initiator, (D) a sensitizer, (E) a hydrogen donor, other components, and a solvent. Incidentally, the blending amounts of the components other than the solvent shown in Tables 2 to 4 are the mass of non-volatile content (amount of the solid content). In addition, evaluation results from the evaluations described later are shown in Tables 2 to 4.

### (Component (A): Binder Polymer)

Binder polymers A-1 to A-2 synthesized by the method was used.

### (Component (B): Photopolymerizable Compound)

B-1: 2,2-Bis(4-(methacryloxypentaethoxy)phenyl)propane (manufactured by Showa Denko Materials Co., Ltd., product name: FA-321M, number of EO groups: 10 (average value))
B-2: (PO)(EO)(PO)-modified polyethylene glycol dimethacrylate (manufactured by Showa Denko Materials Co., Ltd., product name: FA-024M, number of EO groups: 6 (average value), number of PO groups: 12 (average value))
B-3: Ethoxylated bisphenol A dimethacrylate (number of EO groups: 2.6 (average value)) (manufactured by Kyoeisha Chemical Co., Ltd., product name: BP-2EM)
B-4: 2,2-Bis(4-(methacryloxypolyethoxy)phenyl)propane (manufactured by SHIN-NAKAMURA CHEMICAL Co., Ltd., product name: BPE-200, number of EO groups: 4 (average value))
B-5: EO-Modified dipentaerythritol hexaacrylate (manufactured by Nippon Kayaku Co., Ltd., product name: DPEA-12)

### (Component (C): Photopolymerization Initiator)

C-1: 2,2′-Bis(2-chlorophenyl)-4,4′,5,5′-tetraphenyl-1,2-biimidazole (manufactured by Hodogaya Chemical Co., Ltd., product name: B-CIM)

### (Component (D): Sensitizer)

D-1: 1-Phenyl-3-(4-methoxystyryl)-5-(4-methoxyphenyl)pyrazoline
D-2: 9,10-Dibutoxyanthracene (manufactured by Kawasaki Kasei Chemicals Ltd., product name: DBA)
D-3: 4,4′-Bis(diethylamino)benzophenone (manufactured by Hodogaya Chemical Co., Ltd., product name: EAB)

### (Component (E): Hydrogen Donor)

E-1: Leuco crystal violet (manufactured by Yamada Chemical Co., Ltd.)

### (Other Components)

F-1: Malachite green (manufactured by OSAKA ORGANIC CHEMICAL INDUSTRY LTD.) (dye)
F-2: tert-Butylcatechol (manufactured by FUJIFILM Wako Pure Chemical Corporation) (polymerization inhibitor)
F-3: 4-Hydroxy-2,2,6,6-tetramethylpiperidine-N-oxyl (manufactured by ADEKA Corporation, product name: LA-7 RD)
F-4: Benzotriazole derivative (manufactured by SANWA KASEI CORP., product name: SF-808H (heterocyclic compound)
   <Manufacture of Photosensitive Elements without Intermediate Layers (Examples 1 to 4, 6, and 8 to 14, and Comparative Examples 1 to 5)>

A solution of the photosensitive resin composition was uniformly applied onto a support shown in Tables 2 to 4 below. The solution was then dried for 10 minutes in a hot air convection dryer at 90° C., and a photosensitive layer having a thickness shown in Tables 2 to 4 below was formed after the drying. Subsequently, a polyethylene film (manufactured by TAMAPOLY CO., LTD., product name “NF-15A”) was laminated on the photosensitive layer as a protective layer to obtain a photosensitive element.

### <Manufacture of Photosensitive Elements Having Intermediate Layers (Examples 5 and 7)>

60 parts by mass of polyvinyl alcohol (manufactured by Kuraray Co., Ltd., product name: PVA-205, degree of saponification=87% by mole) and 40 parts by mass of polyvinyl pyrrolidone (manufactured by NIPPON SHOKUBAI CO., LTD., product name: K-30) were slowly added to 500 parts by mass of water and 250 parts by mass of 1-propanol at room temperature, and mixed. The mixed liquid was heated to 90° C., stirred for 1 hour, and cooled to room temperature to obtain a resin composition for forming an intermediate layer. Next, the resin composition for forming an intermediate layer was applied onto a support shown in Table 2 below so that the thickness was uniform, and dried for 10 minutes in a hot air convection dryer at 95° C. to form an intermediate layer with a thickness of 5 μm after drying. Next, a solution of the photosensitive resin composition was uniformly applied onto the intermediate layer. Then, the resultant was dried for 10 minutes in a hot air convection dryer at 90° C. to form a photosensitive layer having a thickness shown in Tables 2 to 4 below after drying. Subsequently, a polyethylene film (manufactured by TAMAPOLY CO., LTD., product name “NF-15A”) was laminated as a protective layer on the photosensitive layer to obtain a photosensitive element.

### (Support)

FS-31: Biaxially oriented polyethylene terephthalate film with a three-layer structure having an antistatic layer on the surface opposite to a side where the photosensitive resin composition is applied, and having layers containing fine particles on front and back sides (manufactured by Toray Industries, Inc., product name “FS-31”, thickness: 16 μm, number of particles and the like with a diameter of 5 μm or more: 0 particles/mm², haze: 0.4%)
FB40: Biaxially oriented polyethylene terephthalate film with a three-layer structure having layers containing fine particles on front and back sides (manufactured by Toray Industries, Inc., product name “FB40”, thickness: 16 μm, number of particles and the like with a diameter of 5 μm or more: 1 particle/mm², haze: 0.7%)
R705G: Biaxially oriented polyethylene terephthalate film with a two-layer structure having an antistatic layer on the surface opposite to a side to which the photosensitive resin composition is applied, and having a layer containing fine particles on the surface opposite to the side to which the photosensitive resin composition is applied (manufactured by Mitsubishi Chemical Corporation, product name “R705G”, thickness: 16 μm, number of particles and the like with a diameter of 5 μm or more: 0 particles/mm², haze: 0.4%)

### <Measurement of Absorbance and Light Transmittance>

A photosensitive element was laminated on a surface of slide glass (manufactured by Matsunami Glass Ind., Ltd., white slide glass excise No. 1 S1126). The lamination was performed using a heat roll at 110° C. with a bonding pressure of 0.4 MPa and a roll speed of 1.0 m/min such that the photosensitive layer of the photosensitive element was in contact with the slide glass surface, while the protective layer was peeled. The photosensitive layer was laminated on the slide glass, and then the support was peeled. In a case where an intermediate layer was provided on the support, both the support and the intermediate layer were peeled. In a case where the intermediate layer could not be peeled from the photosensitive layer, a photosensitive element without the intermediate layer consisting of the photosensitive layer and the support was separately manufactured, the photosensitive layer was laminated on the slide glass by the above-described method, and the absorbance and light transmittance were measured. The absorbance and the light transmittance of the photosensitive layer were measured using a U-3310 type spectrophotometer (manufactured by Hitachi High-Tech Science Corporation) under measurement conditions of wavelength range: 330 to 700 nm, scan speed: 300 nm/min, scan interval: 0.50 nm, and slit width: 2 nm. Baseline measurement was performed using untreated slide glass as a reference and a sample. The slide glass on which the photosensitive layer was laminated was placed on the sample side holder and the untreated slide glass was placed on the reference side holder to perform the measurement. The absorbance and the light transmittance at an exposure wavelength (365 nm) were recorded from the obtained absorption spectrum and regarded as the absorbance and the light transmittance of the photosensitive layer, respectively. In addition, an absorbance per 1 μm of thickness was determined by dividing the absorbance of the photosensitive layer by the thickness of the photosensitive layer.

### <Manufacture of Laminate>

A substrate with copper sputtered on a polyethylene terephthalate film (surface roughness Sa: 3 nm, manufactured by GEOMATEC Co., Ltd.; a 10 nm-thick titanium-sputtered film is formed on a flat side surface of a 125 μm-thick polyethylene terephthalate film (manufactured by TOYOBO CO., LTD., product name: A4160), and a 100 nm-thick copper-sputtered film is further formed on the titanium surface) was heated to 80° C., and a photosensitive element was laminated on the copper surface of the substrate. The lamination was performed using a heat roll at 110° C. with a bonding pressure of 0.4 MPa and a roll speed of 1.0 m/min such that the photosensitive layer of the photosensitive element was in contact with the copper surface of the copper substrate, while the protective layer was peeled. Thus, a laminate in which the substrate, the photosensitive layer, and the support were laminated in this order, or a laminate in which the substrate, the photosensitive layer, the intermediate layer, and the support were laminated in this order was obtained. The obtained laminate was used as a test piece for tests shown below.

### <Measurement of Minimum Development Time>

The support was peeled from the test piece to expose the photosensitive layer, and a 1%-by-weight aqueous sodium carbonate solution at 30° C. was sprayed thereonto. The time until the photosensitive layer was completely removed was measured and regarded as a minimum development time.

### <Evaluation of Resolution and Adhesiveness>

A glass chromium-type photo tool (negative for the resolution: one having a wiring pattern with a line width/space width of 3x/x and x/x (x: 1.0 to 18.0 (increments of 0.5), unit: μm), and negative for the adhesiveness: one having a wiring pattern with a line width/space width of x/3x and x/x (x: 1.0 to 18.0 (increments of 0.5), unit: μm)) was placed as a negative for evaluation of the resolution and the adhesiveness on the support of the test piece, and the photosensitive layer was exposed at a predetermined energy amount using a projection exposure apparatus (manufactured by Ushio Inc., product name “UX-2240-SM-XJ01”) having an ultrahigh pressure mercury lamp (365 nm) as a light source. After the exposure, the support was peeled to expose the photosensitive layer, and a 1l %-by-mass aqueous sodium carbonate solution set at 30° C. was sprayed for a time twice or more the minimum developing time to remove the unexposed area (development treatment). It should be noted that in Examples 5 and 7, since the suppression of the progress of a photocuring reaction caused by the inhibition of radical polymerization due to oxygen in the air can be reduced by providing an intermediate layer having gas barrier properties, the support was peeled, and then a photo tool was placed on the intermediate layer and exposed in order to form an excellent resist pattern by exposure without using the support.

After the development treatment, the resolution and the adhesiveness were evaluated by the minimum value of the line width/space width for resist patterns formed with cleanly removed space areas (unexposed areas), and without twists, meandering, and chipping of the line areas (exposed areas). At this time, the value of the line width/space width evaluated using the exposure amount at which the resist line width with a line width/space width of the pattern negative for the adhesiveness (x/x)=10 μm/10 μm is 10.0 μm as the predetermined energy amount was recorded as the resolution (3x/x) and the adhesiveness (x/3x). The smaller this numerical value, the better the resolution and the adhesiveness.

### <Evaluation of Resist Shape>

For the pattern with a line width/space width=8 μm/8 μm among the resist patterns after the development treatment, the line widths of the upper part (x) and the bottom part (y) were measured using a scanning electron microscope (SEM, product name SU-1500, manufactured by Hitachi High-Tech Co., Ltd.), acceleration voltage: 15.0 kV). A taper ratio (x/y) was determined as evaluation criteria of the resist shape from the measured values. As the taper ratio is closer to 1, the resist shape is closer to a rectangle, which can be said to be good. The resist shape having a taper ratio of 0.85 or more and less than 1.1 was evaluated as “A” and the resist shape having a taper ratio of less than 0.85 was evaluated as “B”.

### (Test for Measurement of Generation of Micro-Defective Parts in Resist)

In order to examine the generation of micro-defective parts in resists in some of Examples, a glass chromium-type photo tool (negative for the adhesiveness: one having a wiring pattern with a line width/space width of 15/15 μm) was placed as a negative for measurement of the generation of micro-defective parts on the support of the test piece, and the photosensitive layer was exposed at a predetermined energy amount using a projection exposure apparatus (manufactured by Ushio Inc., product name “UX-2240-SM-XJ01”) having an ultrahigh pressure mercury lamp (365 nm) as a light source. It should be noted that in Example 5, since the suppression of the progress of a photocuring reaction caused by the inhibition of radical polymerization due to oxygen in the air can be reduced by providing an intermediate layer having gas barrier properties, the support was peeled and a photo tool was then placed on the intermediate layer and exposed in order to form an excellent resist pattern by exposure without using the support. At this time, the exposure amount at which the resist line width with a line width/space width of the pattern negative for the adhesiveness (x/x)=10 μm/10 μm is 10.0 μm in <Evaluation of Resolution and Adhesiveness> was regarded as the predetermined energy amount. After the exposure, the support was peeled to expose the photosensitive layer, and a 1%-by-mass aqueous sodium carbonate solution at 30° C. was sprayed for twice the minimum development time to remove unexposed area (development treatment). Next, the number of defective parts in the resist, in which the resist was defective by 5 μm or more, was counted using a microscope or an automated optical inspection apparatus (AOI). The observation unit was a line length of 1 mm and the number of lines of 5000, and an average value in a case where n was 5 was taken as the number of the micro-defective parts in the resist. With regard to the number of the micro-defective parts in the resist, the number of generation of the defects of less than 10 was evaluated as “A” and the number of generation of the defects of 10 or more was evaluated “B”.

TABLE 2

| | | Example | | | | | | |
|---|---|---|---|---|---|---|---|---|
| Item | | 1 | 2 | 3 | 4 | 5 | 6 | 7 |
| Component (A) | A-1 | 57.0 | 55.4 | 55.4 | 55.4 | 55.4 | 55.4 | 55.4 |
| | A-2 | — | — | — | — | — | — | — |
| Component (B) | B-1 | 34.5 | 35.8 | 35.8 | 35.8 | 35.8 | 35.8 | 35.8 |
| | B-2 | 2.5 | 2.6 | 2.6 | 2.6 | 2.6 | 2.6 | 2.6 |
| | B-3 | 6.0 | 6.2 | 6.2 | 6.2 | 6.2 | 6.2 | 6.2 |
| | B-4 | — | — | — | — | — | — | — |
| | B-5 | — | — | — | — | — | — | — |
| Component (C) | C-1 | 5.50 | 5.70 | 5.70 | 5.70 | 5.70 | 5.70 | 5.70 |
| Component (D) | D-1 | 0.0270 | 0.0280 | 0.0280 | 0.0280 | 0.0280 | 0.0280 | 0.0280 |
| | D-2 | — | — | — | — | — | — | — |
| | D-3 | — | — | — | — | — | — | — |
| Component (E) | E-1 | 0.770 | 0.800 | 0.800 | 0.800 | 0.800 | 0.800 | 0.800 |
| Other components | F-1 | 0.05 | 0.05 | 0.05 | 0.05 | 0.05 | 0.05 | 0.05 |
| | F-2 | 0.040 | 0.041 | 0.041 | 0.041 | 0.041 | 0.041 | 0.041 |
| | F-3 | 0.01 | 0.01 | 0.01 | 0.01 | 0.01 | 0.01 | 0.01 |
| | F-4 | 1.0 | 1.0 | 1.0 | 1.0 | 1.0 | 1.0 | 1.0 |
| Organic solvent | Methanol | 6.0 | 6.0 | 6.0 | 6.0 | 6.0 | 6.0 | 6.0 |
| | Toluene | 16.0 | 16.5 | 16.5 | 16.5 | 16.5 | 16.5 | 16.5 |
| | Acetone | 10.0 | 10.5 | 10.5 | 10.5 | 10.5 | 10.5 | 10.5 |

| | | | | | | | |
|---|---|---|---|---|---|---|---|
| Thickness (μm) of | 25 | 25 | 25 | 25 | 25 | 15 | 15 |
| photosensitive layer | | | | | | | |
| Support | FS-31 | FS-31 | FB40 | R705G | FS-31 | FS-31 | FS-31 |
| Intermediate layer | Absent | Absent | Absent | Absent | Present | Absent | Present |
| Absorbance | 0.168 | 0.175 | 0.175 | 0.175 | 0.175 | 0.105 | 0.105 |
| Absorbance per 1 μm of | 0.0067 | 0.0070 | 0.0070 | 0.0070 | 0.0070 | 0.0070 | 0.0070 |
| photosensitive layer | | | | | | | |
| Light transmittance (%) | 67.9 | 66.8 | 66.8 | 66.8 | 66.8 | 78.5 | 78.5 |
| Minimum development time | 25 | 22 | 22 | 22 | 28 | 14 | 20 |
| (seconds) | | | | | | | |
| Predetermined energy amount | 140 | 130 | 130 | 130 | 120 | 130 | 120 |
| (mJ/cm²) | | | | | | | |
| Resolution 3×/× (μm) | 5.0 | 5.0 | 5.0 | 5.0 | 5.0 | 4.5 | 4.5 |
| Adhesiveness ×/3× (μm) | 7.0 | 7.0 | 7.0 | 7.0 | 7.0 | 4.5 | 4.5 |
| Resist shape | A | A | A | A | A | A | A |
| Number of generation of | — | A | B | A | — | — | — |
| micro-defective parts in resist | | | | | | | |

TABLE 3

| | | Example | | | | | | |
|---|---|---|---|---|---|---|---|---|
| Item | | 8 | 9 | 10 | 11 | 12 | 13 | 14 |
| Component (A) | A-1 | — | 55.4 | 55.4 | 55.4 | 55.4 | 55.4 | 55.4 |
| | A-2 | 55.4 | — | — | — | — | — | — |
| Component (B) | B-1 | 35.8 | 35.8 | 35.8 | 35.8 | 35.8 | 35.8 | 35.8 |
| | B-2 | 2.6 | 2.6 | 2.6 | 2.6 | 2.6 | 2.6 | 2.6 |
| | B-3 | 6.2 | 6.2 | 6.2 | 6.2 | 6.2 | 6.2 | 6.2 |
| | B-4 | — | — | — | — | — | — | — |
| | B-5 | — | — | — | — | — | — | — |
| Component (C) | C-1 | 5.70 | 5.70 | 5.70 | 5.70 | 5.70 | 8.03 | 5.70 |
| Component (D) | D-1 | 0.0280 | — | — | — | 0.0280 | — | 0.0746 |
| | D-2 | — | 0.1349 | — | — | — | — | — |
| | D-3 | — | — | 0.0196 | — | — | — | — |
| Component (E) | E-1 | 0.800 | 0.800 | 0.800 | 0.800 | 0.560 | 0.800 | 0.800 |
| Other components | F-1 | 0.05 | 0.05 | 0.05 | 0.05 | 0.05 | 0.05 | 0.05 |
| | F-2 | 0.041 | 0.041 | 0.041 | 0.041 | 0.041 | 0.041 | 0.041 |
| | F-3 | 0.01 | 0.01 | 0.01 | 0.01 | 0.01 | 0.01 | 0.01 |
| | F-4 | 1.0 | 1.0 | 1.0 | 1.0 | 1.0 | 1.0 | 1.0 |
| Organic solvent | Methanol | 6.0 | 6.0 | 6.0 | 6.0 | 6.0 | 6.0 | 6.0 |
| | Toluene | 16.0 | 16.5 | 16.5 | 16.5 | 16.5 | 24.0 | 16.5 |
| | Acetone | 10.0 | 10.5 | 10.5 | 10.5 | 10.5 | 5.5 | 10.5 |

| | | | | | | | |
|---|---|---|---|---|---|---|---|
| Thickness (μm) of | 25 | 25 | 25 | 25 | 25 | 25 | 25 |
| photosensitive layer | | | | | | | |
| Support | FS-31 | FS-31 | FS-31 | FS-31 | FS-31 | FS-31 | FS-31 |
| Intermediate layer | Absent | Absent | Absent | Absent | Absent | Absent | Absent |
| Absorbance | 0.175 | 0.186 | 0.191 | 0.116 | 0.170 | 0.150 | 0.243 |
| Absorbance per 1 μm of | 0.0070 | 0.0074 | 0.0076 | 0.0046 | 0.0068 | 0.0060 | 0.0097 |
| photosensitive layer | | | | | | | |
| Light transmittance (%) | 66.8 | 65.2 | 64.4 | 76.6 | 67.6 | 70.8 | 57.1 |
| Minimum development time | 26 | 22 | 22 | 22 | 22 | 30 | 22 |
| (seconds) | | | | | | | |
| Predetermined energy amount | 130 | 130 | 130 | 160 | 130 | 130 | 120 |
| (mJ/cm²) | | | | | | | |
| Resolution 3×/× (μm) | 5.0 | 5.0 | 5.0 | 5.0 | 5.0 | 5.0 | 5.5 |
| Adhesiveness ×/3× (μm) | 7.0 | 7.0 | 7.0 | 7.0 | 7.0 | 7.0 | 8.0 |
| Resist shape | A | A | A | A | A | A | A |

TABLE 4

| | | Comparative Example | | | | |
|---|---|---|---|---|---|---|
| Item | | 1 | 2 | 3 | 4 | 5 |
| Component (A) | A-1 | — | — | 55.4 | 55.4 | — |
| | A-2 | 57.0 | 53.0 | — | — | 55.0 |
| Component (B) | B-1 | 28.0 | 23.0 | 35.8 | 35.8 | 30.0 |
| | B-2 | 5.0 | 2.5 | 2.6 | 2.6 | 5.0 |
| | B-3 | — | — | 6.2 | 6.2 | — |
| | B-4 | 10.0 | 19.0 | — | — | 10.0 |
| | B-5 | — | 2.5 | — | — | — |
| Component (C) | C-1 | 2.90 | 2.90 | 5.70 | 5.70 | 2.90 |
| Component (D) | D-1 | — | — | 0.1212 | 0.2144 | 0.0100 |
| | D-2 | — | — | — | — | — |
| | D-3 | 0.0830 | 0.0830 | — | — | — |
| Component (E) | E-1 | 0.30 | 0.30 | 0.800 | 0.800 | 0.50 |
| Other components | F-1 | 0.05 | 0.05 | 0.05 | 0.05 | 0.05 |
| | F-2 | 0.024 | 0.026 | 0.041 | 0.041 | — |
| | F-3 | — | — | 0.01 | 0.01 | — |
| | F-4 | 1.0 | 1.0 | 1.0 | 1.0 | — |
| Organic solvent | Methanol | 5.0 | 5.0 | 6.0 | 6.0 | 10.0 |
| | Toluene | 9.0 | 9.0 | 16.5 | 16.5 | 10.0 |
| | Acetone | 5.0 | 5.0 | 10.5 | 10.5 | 10.0 |

| | | | | | |
|---|---|---|---|---|---|
| Thickness (μm) of | 25 | 25 | 25 | 25 | 25 |
| photosensitive layer | | | | | |
| Support | FB40 | FB40 | FS-31 | FS-31 | FB40 |
| Intermediate layer | Absent | Absent | Absent | Absent | Absent |
| Absorbance | 0.328 | 0.331 | 0.345 | 0.452 | 0.103 |
| Absorbance per 1 μm of | 0.0131 | 0.0132 | 0.0138 | 0.0181 | 0.0041 |
| photosensitive layer | | | | | |
| Light transmittance (%) | 47.0 | 46.7 | 45.2 | 35.3 | 79.0 |
| Minimum development time | 21 | 21 | 22 | 22 | 22 |
| (seconds) | | | | | |
| Predetermined energy amount | 120 | 120 | 100 | 90 | 120 |
| (mJ/cm²) | | | | | |
| Resolution 3×/× (μm) | 8.0 | 8.0 | 6.0 | 6.0 | 8.0 |
| Adhesiveness ×/3× (μm) | 9.0 | 9.0 | 9.0 | 11 | 9.0 |
| Resist shape | B | B | B | B | A |

### REFERENCE SIGNS LIST

1: photosensitive element, 2: support, 3: photosensitive layer, 4: protective layer.

1. A photosensitive resin composition comprising:
(A) a binder polymer;
(B) a photopolymerizable compound having an ethylenically unsaturated bond; and
(C) a photopolymerization initiator,
wherein the photosensitive resin composition has an absorbance with respect to light at a wavelength of 365 nm per 1 μm of thickness of more than 0.0041 and 0.0130 or less.

2. The photosensitive resin composition according to claim 1,
wherein the photosensitive resin composition has an absorbance with respect to light at a wavelength of 365 nm per 1 μm of thickness of 0.0080 or less.

3. The photosensitive resin composition according to claim 1,
wherein a content of the (C) photopolymerization initiator is 3.0 parts by mass or more with respect to 100 parts by mass of a total amount of the (A) binder polymer and the (B) photopolymerizable compound.

4. The photosensitive resin composition according to claim 1,
wherein a content of the (C) photopolymerization initiator is 5.0 parts by mass or more with respect to 100 parts by mass of a total amount of the (A) binder polymer and the (B) photopolymerizable compound.

5. The photosensitive resin composition according to claim 1, further comprising (D) a sensitizer.

6. The photosensitive resin composition according to claim 5,
wherein the (D) sensitizer includes at least one selected from the group consisting of a dialkylaminobenzophenone compound, a pyrazoline compound, an anthracene compound, and a coumarin compound.

7. The photosensitive resin composition according to claim 5,
wherein a content of the (D) sensitizer is 0.03 parts by mass or less with respect to 100 parts by mass of the total amount of the (A) binder polymer and the (B) photopolymerizable compound.

8. The photosensitive resin composition according to claim 5,
wherein a mass ratio of a content of the (C) photopolymerization initiator to a content of the (D) sensitizer (the content of the (C) photopolymerization initiator/the content of the (D) sensitizer) is 80 or more.

9. The photosensitive resin composition according to claim 1, further comprising (E) a hydrogen donor,
wherein a content of the (E) hydrogen donor is 0.3 parts by mass or more with respect to 100 parts by mass of a total amount of the (A) binder polymer and the (B) photopolymerizable compound.

10. The photosensitive resin composition according to claim 9,
wherein the content of the (E) hydrogen donor is 0.55 parts by mass or more with respect to 100 parts by mass of the total amount of the (A) binder polymer and the (B) photopolymerizable compound.

11. The photosensitive resin composition according to claim 9,
wherein a total content of the (C) photopolymerization initiator and the (E) hydrogen donor is 4.0 parts by mass or more with respect to 100 parts by mass of the total amount of the (A) binder polymer and the (B) photopolymerizable compound.

12. The photosensitive resin composition according to claim 1,
wherein the photosensitive resin composition is used for formation of a resist pattern using a projection exposure system.

13. A photosensitive element comprising:
a support; and
a photosensitive layer including the photosensitive resin composition according claim 1 formed on the support.

14. The photosensitive element according to claim 13,
wherein the support has a haze of 0.01% to 1.0%.

15. The photosensitive element according to claim 13,
wherein the number of particles having a diameter of 5 μm or more included in the support is 5 particles/mm² or less.

16. The photosensitive element according to claim 13,
wherein an intermediate layer containing a polyvinyl alcohol is provided between the support and the photosensitive layer.

17. A method for forming a resist pattern, the method comprising:
a photosensitive layer forming step of laminating a photosensitive layer including the photosensitive resin composition according to claim 1 on a substrate;
an exposure step of irradiating a predetermined portion of the photosensitive layer with active light rays to form a photocured area; and
a development step of removing an area other than the predetermined portion of the photosensitive layer from the substrate.

18. A method for forming a resist pattern, the method comprising:
a photosensitive layer forming step of laminating the photosensitive layer of the photosensitive element according to claim 13 on a substrate;
an exposure step of irradiating a predetermined portion of the photosensitive layer with active light rays to form a photocured area; and
a development step of removing an area other than the predetermined portion of the photosensitive layer from the substrate.

19. A method for producing a semiconductor package substrate or printed wiring board, the method comprising:
a step of subjecting a substrate on which a resist pattern is formed by the method for forming a resist pattern according to claim 17 to an etching treatment or a plating treatment to form a conductor pattern.

20. A method for producing a semiconductor package substrate or printed wiring board, the method comprising:
a step of subjecting a substrate on which a resist pattern is formed by the method for forming a resist pattern according to claim 18 to an etching treatment or a plating treatment to form a conductor pattern.
